(19) United States
(12) Patent Application Publication
(10) Pub. No.: US 2011/0024880 A1
(43) Pub. Date: Feb. 3, 2011

(54) NANO-PATTERNED SUBSTRATE AND EPITAXIAL STRUCTURE

(75) Inventors: Zhen-Yu Li, Chiayi County (TW); Ching-Hua Chiu, Taipei City (TW); Hao-Chung Kuo, Hsinchu City (TW); Tien-Chang Lu, Taoyuan County (TW)

Correspondence Address: WPAT, PC;INTELLECTUAL PROPERTY ATTORNEYS, 7225 BEVERLY ST., ANNANDALE, VA, 22003, US

(73) Assignees: EPISTAR CORPORATION, Hsinchu (TW); Sino-American Silicon Products.Inc., Hsinchu (TW)

(21) Appl. No.: 12/846,364

(22) Filed: Jul. 29, 2010

(30) Foreign Application Priority Data
Jul. 30, 2009 (TW) 098214077

(51) Int. Cl. H01L 29/06; H01L 21/20

(52) U.S. Cl. 257/618; 438/478; 257/E29.005; 257/E21.09

(57) ABSTRACT

A nano-patterned substrate includes a plurality of nano-particles or nanopillars on an upper surface thereof. A ratio of height to diameter of each of the nano-particles or each of the nanopillars is either greater than or equal to 1. Particularly, a ratio of height to diameter of the nanopillars is greater than or equal to 5. Each of the nano-particles or each of the nanopillars has an arc-shaped top surface. When an epitaxial growth process is applied onto the nano-patterned substrate to form an epitaxial layer, the epitaxial layer has very low defect density. Thus, a production yield of fabricating the subsequent device can be improved.

### CROSS-REFERENCE TO RELATED APPLICATION

This application claims the right of priority based on TW application Ser. No. 098214077, filed Jul. 30, 2009, entitled “NANO-PATTERNED SUBSTRATE AND EPITAXIAL STRUCTURE”, and the contents of which are incorporated herein by reference.

### BACKGROUND

1. Technical Field

The present disclosure relates to a nano-patterned substrate and an epitaxial structure, and particularly to a nano-patterned substrate and an epitaxial structure of an LED.

2. Description of the Related Art

Compared to a conventional bulb, a light emitting diode (LED) has many advantages like small size, long lifetime, low driving voltage/current, high resistance to damage, low heat accumulation, no pollution from mercury, and high light-emitting efficiency (low power consumption), and so on. Since the light emitting efficiency of LEDs has been increasingly improved, LEDs have been substituting for conventional bulbs such as fluorescent lamps and incandescent lamps in various fields gradually. For example, an LED device can be widely used as a light source of a high performance scanner, a backlight or a front light source of a liquid crystal display, a dashboard lighting device of an automobile, a traffic light and a general lighting device.

Furthermore, because a III-V compound with a nitride element has a wide energy band gap, the emission wavelength of the compound substantially covers a range from ultraviolet to red. In other words, the emission wavelength of the nitride compound covers almost the entire visible light band. Therefore, an LED based on a semiconductor compound, particularly gallium nitride, e.g. gallium nitride (GaN), aluminum gallium nitride (AlGaN), indium gallium nitride (InGaN), etc., has been widely used in various light emitting modules.

FIG. 1 schematically illustrates a cross-sectional view of a conventional LED. Referring to FIG. 1, an LED 100 includes a substrate 110, a first conductivity type semiconductor layer 120, an electrode 122, a light emitting layer 130, a second conductivity type semiconductor layer 140, an ohmic contact layer 150 and an electrode 142. The first conductivity type semiconductor layer 120, the light emitting layer 130, the second conductivity type semiconductor layer 140, the ohmic contact layer 150 and the electrode 142 are disposed on the substrate 110. The first conductivity type semiconductor layer 120 is partially covered by the light emitting layer 130. The electrode 122 is disposed on the first conductivity type semiconductor layer 120 that is not covered by the light emitting layer 130.

In general, the first conductivity type semiconductor layer 120 is formed by an epitaxial growth process on the substrate of a material like sapphire or silicon carbide (SiC). Generally, an epitaxial growth surface of the substrate is a flat plane. When the epitaxial growth process is directly applied onto the epitaxial growth surface of the substrate, defects likely occur when the process proceeds to growth of quantum wells. Thus, the defect density of the first conductivity type semiconductor layer is very high. As a result, not only the production yield of subsequent components is affected, but also the light emitting efficiency and the electron mobility of the LED are reduced. Therefore, the LED cannot exhibit high light emitting efficiency.

### SUMMARY

The present disclosure provides a nano-patterned substrate rendering minimized defects in an epitaxial structure based on the nano-patterned substrate.

The present disclosure also provides an epitaxial structure with reduced defects therein.

The present disclosure provides a nano-patterned substrate, which includes a substrate having an upper surface; and a plurality of nano-particles formed on the upper surface of the substrate, having a ratio of height to diameter greater than or equal to 1, and having an arc-shaped top surface.

The present disclosure provides another nano-patterned substrate, which includes a substrate; a semiconductor buffer layer formed on the substrate; and a plurality of nanopillars formed on the semiconductor buffer layer, having a ratio of height to diameter greater than or equal to 5, and having an arc-shaped top surface.

The present disclosure further provides an epitaxial structure, comprising a nano-patterned substrate, which includes a substrate having an upper surface and a plurality of nano-structures formed on the upper surface of the substrate at intervals, having a ratio of height to diameter greater than or equal to 1, and having an arc-shaped top surface; and an epitaxial layer formed on the nano-patterned substrate and covering the nano-structures.

Other objectives, features and advantages of the present disclosure will be further understood from the further technological features disclosed by the embodiments of the present disclosure wherein there are shown and described preferred embodiments of this disclosure, simply by way of illustration of modes best suited to carry out the disclosure.

### BRIEF DESCRIPTION OF THE DRAWINGS

The accompanying drawings are included to provide easy understanding of the invention, and are incorporated herein and constitute a part of this specification. The drawings illustrate embodiments of the invention and, together with the description, serve to illustrate the principles of the invention.

FIG. 1 schematically illustrates a cross-sectional view of a conventional LED.

FIG. 2 schematically illustrates a nano-patterned substrate in accordance with a first embodiment of the present disclosure.

FIG. 3 schematically illustrates an enlarged view of a nano-particle.

FIG. 4 schematically illustrates a growth process of the nano-patterned substrate in accordance with the first embodiment of the present disclosure.

FIG. 5 schematically illustrates a nano-patterned substrate in accordance with a second embodiment of the present disclosure.

FIG. 6 schematically illustrates a schematic view of a growth process of the nano-patterned substrate in accordance with the second embodiment of the present disclosure.

FIG. 7 schematically illustrates a nano-patterned substrate in accordance with a third embodiment of the present disclosure.

FIG. 8 schematically illustrates an enlarged view of a nanopillar.

FIG. 9 schematically illustrates a growth process of the nano-patterned substrate in accordance with the third embodiment of the present disclosure.

FIG. 10 schematically illustrates an epitaxial structure based on the nano-patterned substrate in accordance with the third embodiment of the present disclosure.

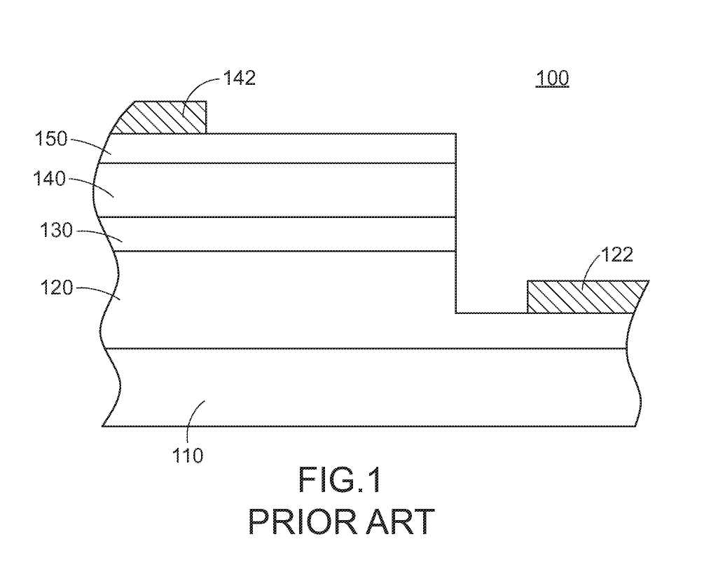

### DESCRIPTION OF THE PREFERRED EMBODIMENTS

It is to be understood that other embodiment may be utilized and structural changes may be made without departing from the scope of the present disclosure. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Furthermore, similar elements in different embodiments share the same numeral references. These elements, although exhibiting similar functions or structures, do not have to be the same in each aspect. For example, they may be different in material, configuration, etc.

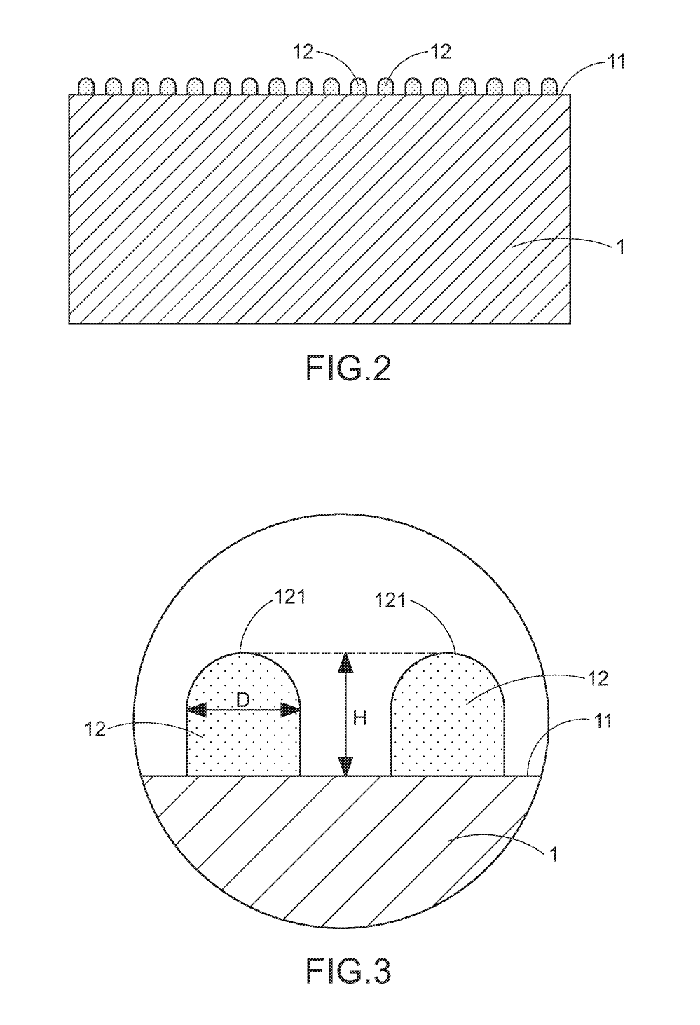

Referring to FIG. 2, a nano-patterned substrate in accordance with a first embodiment of the present disclosure is shown. The nano-patterned substrate 1 includes an upper surface 11. A plurality of nano-particles 12 is disposed on the upper surface 11. Further, referring to FIG. 3, an aspect ratio of each of the nano-particles 12, that is, the ratio of height (H) to diameter (D), is either greater than or equal to 1 (i.e., H/D≧1) and each of the nano-particles 12 has an arc-shaped top surface 121.

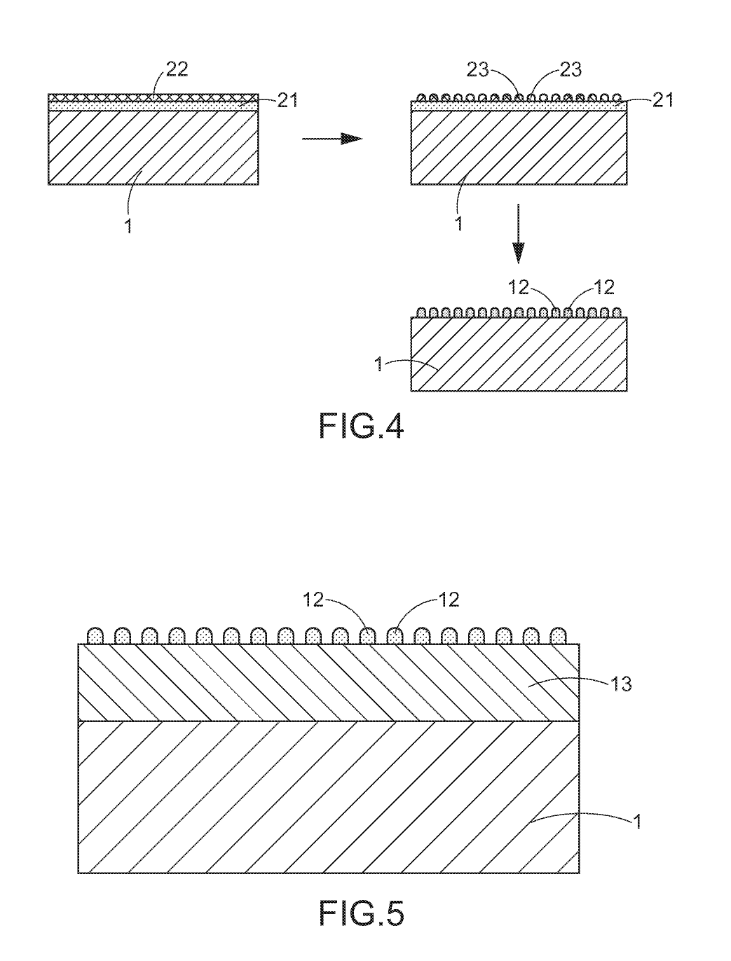

FIG. 4 schematically illustrates a growth process of the nano-patterned substrate in accordance with first embodiment of the present disclosure. Referring to FIG. 4, a buffer layer 21 is formed on the upper surface 11 of the substrate 1. In one embodiment of this disclosure, the material of the buffer layer can be silicon oxide. A metal layer 22 is then formed on the buffer layer 21. A material of the metal layer 22 can be nickel. A thickness of the metal layer 22 is in a range from 50 angstroms to 200 angstroms. A thermal treatment is applied to the metal layer 22 so that a plurality of nanoscale metal particles 23 is formed. A temperature of the thermal treatment is approximately 850° C. Next, an etching process is performed. In the etching process, the nanoscale metal particles 23 are used as a mask. The etching process is, for example, an inductively-coupled plasma reactive ion etching (ICP-RIE). Next, an acid etching process is performed. For example, the substrate 1 is put into a nitric acid etching solution at 100° C. so as to remove the remaining nanoscale metal particles 23. As a result, the buffer layer 21 is transformed into a plurality of nano-particles 12.

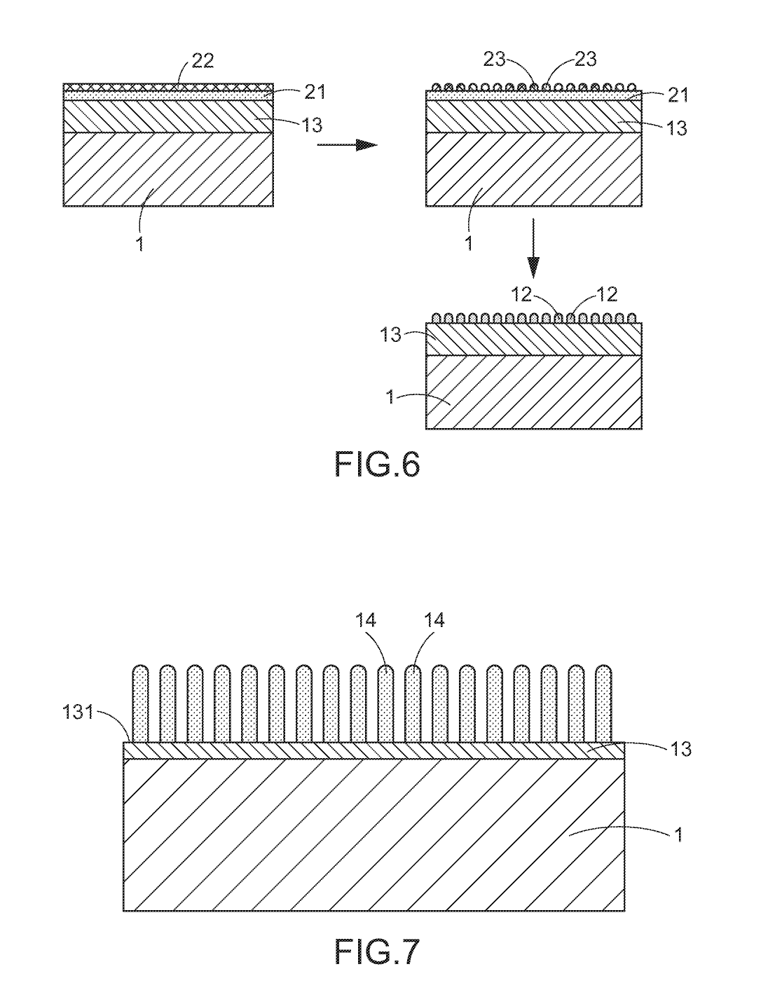

FIG. 5 schematically illustrates a nano-patterned substrate in accordance with a second embodiment of the present disclosure. A semiconductor buffer layer 13 is disposed between a substrate 1 and a plurality of nano-particles 12. The material of the semiconductor buffer layer 13 comprises at least one element selected from the group consisting of Ga, Al, In, As, P, N, Si, and any combination thereof. The formation of the nano-patterned substrate in the second embodiment is similar to the formation of the nano-patterned substrate in the first embodiment. Referring to FIG. 6, the semiconductor buffer layer 13 is formed on an upper surface 11 of the substrate 1. A buffer layer 21 is formed on the semiconductor buffer layer 13. In one embodiment of this disclosure, the material of the buffer layer can be silicon oxide. A metal layer 22 is then formed on the semiconductor buffer layer 13. Thermal treatment is applied to the metal layer 22 so that nanoscale metal particles 23 are formed. Next, the buffer layer 21 is etched to form the plurality of nano-particles 12.

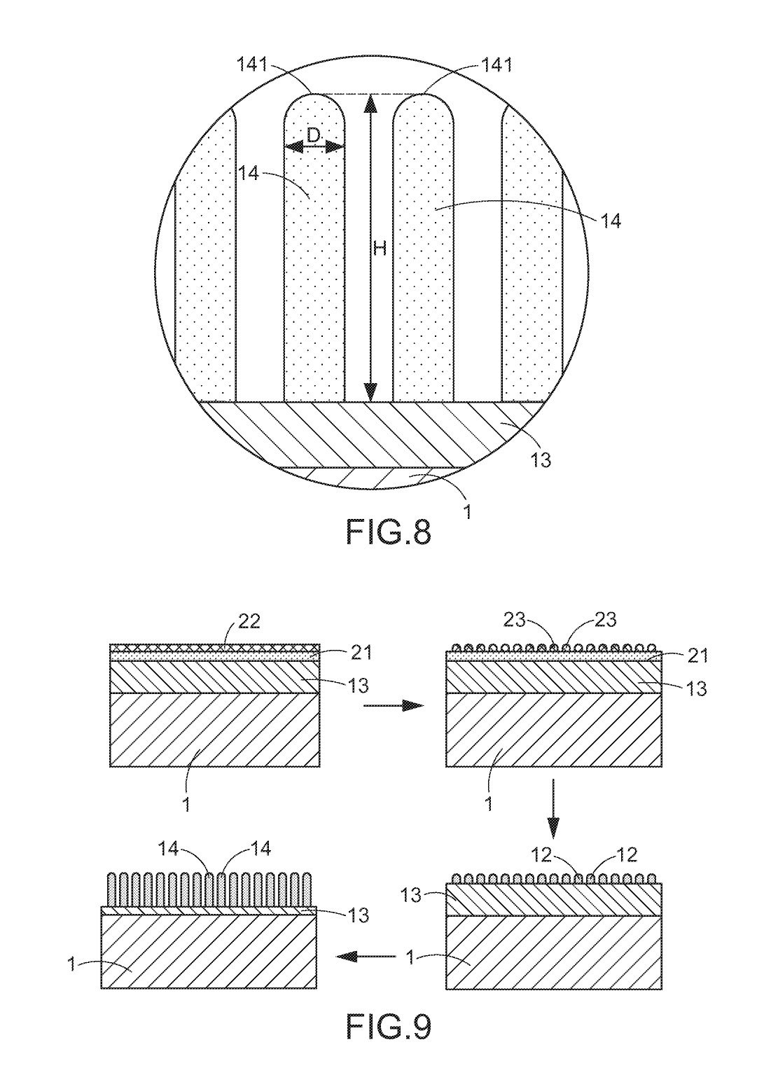

FIG. 7 illustrates a schematic view of a nano-patterned substrate in accordance with a third embodiment of the present disclosure. Referring to FIG. 7, the nano-patterned substrate includes a semiconductor buffer layer 13 disposed on the substrate 1, and a plurality of nanopillors 14 is formed on an upper surface 131 of the semiconductor buffer layer 13. An aspect ratio of the nanopillars 14, that is, the ratio of height (H) to diameter (D) is either greater than or equal to 5 (i.e., H/D≧5). Further, referring to FIG. 8, each of the nanopillars 14 has an arc-shaped top surface 141.

The formation of the nano-patterned substrate in the third embodiment is similar to the formation of the nano-patterned substrate in the first embodiment. Referring to FIG. 9, the semiconductor buffer layer 13 is formed on the substrate 1. A buffer layer 21 is formed on the semiconductor buffer layer 13. In one embodiment of this disclosure, the material of the buffer layer can be silicon oxide. A metal layer 22 is then formed on the semiconductor buffer layer 13. Thermal treatment is applied to the metal layer 22 so that nanoscale metal particles 23 are formed. Next, the buffer layer 21 and the semiconductor buffer layer 13 are etched to form the nanopillars 14 with the high aspect ratio.

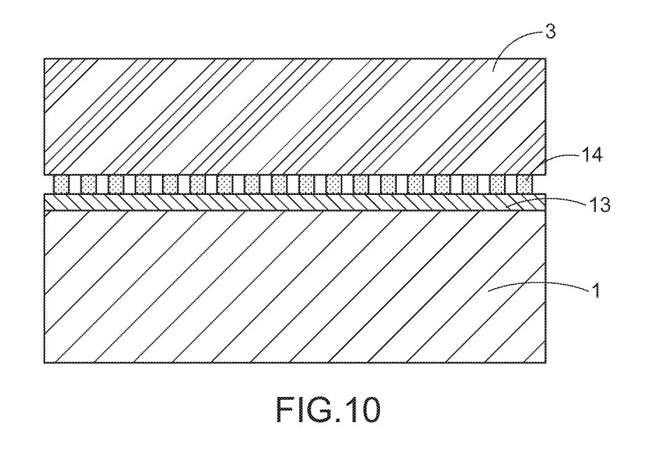

Any of the above described nano-patterned substrates is suitable to be used in an epitaxial lateral overgrowth process of a semiconductor material. For example, FIG. 10 illustrates an epitaxial structure based on the nano-patterned substrate in accordance with the third embodiment of the present disclosure. Referring to FIG. 10, an epitaxial layer 3 is formed on the substrate 1 having the nanopillars 14 (or nano-particles 12 in another embodiment) and covers the nanopillars 14 (or nano-particles 12 in another embodiment). The nanopillars 14 (or nano-particles 12 in another embodiment) formed on the substrate 1 can restrain epitaxial vertical growth and enlarge lateral epitaxial area due to relatively high aspect ratio, thereby improving the quality of the epitaxial layer 3. Thus, the tunneling defects resulting from the lattice mismatch can be reduced, and thus the epitaxial layer can be formed with low defect density. Further, the internal quantum efficiency of the epitaxial layer can be improved. If the substrate formed thereon with the epitaxial layer is applied to a light-emitting device, the light emitting efficiency of the light-emitting device can be enhanced. The resulting substrate is further advantageous in reflecting downward light upwardly by the nano-particles or nanopillars made of silicon oxide, and the reflected light may join the emitted light so as to enhance the emitting light intensity.

The above description is given by way of example, and not limitation. Given the above disclosure, one having ordinary skill in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A nano-patterned substrate, comprising:
a substrate having an upper surface; and
a plurality of nano-structures formed on the upper surface of the substrate, having a ratio of height to diameter greater than or equal to 1, and having an arc-shaped top surface.

2. The nano-patterned substrate as claimed in claim 1, further comprising a semiconductor buffer layer disposed between the substrate and the nano-structures.

3. The nano-patterned substrate as claimed in claim 2, wherein the material of the semiconductor buffer layer comprises at least one element selected from the group consisting of Ga, Al, In, As, P, N, Si, and any combination thereof.

4. The nano-patterned substrate as claimed in claim 1, wherein the nano-structures are formed of silicon oxide.

5. The nano-patterned substrate as claimed in claim 1, wherein the nano-structures are nano-particles having a ratio of height to diameter greater than or equal to 1, or the nano-structures are nanopillars having a ratio of height to diameter greater than or equal to 5.

6. An epitaxial structure, comprising:
a nano-patterned substrate comprising:
a substrate having an upper surface; and
a plurality of nano-structures formed on the upper surface of the substrate at intervals, having a ratio of height to diameter greater than or equal to 1, and having an arc-shaped top surface; and
an epitaxial layer formed on the nano-patterned substrate and covering the nano-structures.

7. The epitaxial structure as claimed in claim 6, wherein the nano-patterned substrate further comprises a semiconductor buffer layer disposed between the substrate and the nano-structures.

8. The epitaxial structure as claimed in claim 7, wherein the material of the semiconductor buffer layer comprises at least one element selected from the group consisting of Ga, Al, In, As, P, N, Si, and any combination thereof.

9. The epitaxial structure as claimed in claim 6, wherein the nano-structures are formed of silicon oxide.

10. The epitaxial structure as claimed in claim 6, wherein the nano-structures are nano-particles having the ratio of height to diameter greater than or equal to 1, or the nano-structures are nanopillars having the ratio of height to diameter greater than or equal to 5.

11. A method of fabricating a nano-patterned substrate comprising:
providing a substrate:
forming a buffer layer on the substrate;
forming a metal layer on the buffer layer;
forming a plurality of nanoscale metal particles by applying a thermal treatment onto the metal layer; and
forming a plurality of nano-structures having a ratio of height to diameter greater than or equal to 1, and having an arc-shaped top surface by etching the buffer layer with the nanoscale metal particles serving as a mask.

12. The method of fabricating the nano-patterned substrate of claim 11, wherein the material of the metal layer can be nickel with the thickness in a range from 50 angstroms to 200 angstroms.

13. The method of fabricating the nano-patterned substrate of claim 11, wherein the buffer layer is etched by an inductively-coupled plasma reactive ion etching.

14. The method of fabricating a nano-patterned substrate of claim 11, further comprising forming a semiconductor buffer layer between the substrate and the buffer layer.

15. The method of fabricating a nano-patterned substrate of claim 14, wherein the material of the semiconductor buffer layer comprises at least one element selected from the group consisting of Ga, Al, In, As, P, N, Si, and any combination thereof.

16. The method of fabricating a nano-patterned substrate of claim 14, wherein the buffer layer and the nano-structures are formed of silicon oxide.

17. The method of fabricating a nano-patterned substrate of claim 14, wherein the nano-structures are nano-particles having the ratio of height to diameter greater than or equal to 1 or the nano-structures are nanopillars having the ratio of height to diameter greater than or equal to 5.

18. The method of fabricating a nano-patterned substrate of claim 14, further comprising forming an epitaxial layer on the substrate and covering the plurality of nano-structures.
